(19) United States
(12) Patent Application Publication
(10) Pub. No.: US 2026/0317889 A1
(43) Pub. Date: Oct. 15, 2026

(54) COPPER-BACKED CERAMIC RING-SEGMENT TARGET

(71) Applicant: PLANSEE COMPOSITE MATERIALS GMBH, Lechbruck am See (DE)

(72) Inventors: Peter POLCIK, Lechbruck am See (DE); Matthias PERL, Lechbruck am See (DE); Marcus WOLFF, Lechbruck am See (DE)

(21) Appl. No.: 19/484,999

(22) PCT Filed: Apr. 11, 2024
(86) PCT No.: PCT/EP2024/059882

§ 371 Date: Nov. 17, 2025

(30) Foreign Application Priority Data
May 16, 2023 (AT) GM50087/2023

(51) Int. Cl. C23C 14/34

(52) U.S. Cl. CPC C23C 14/3414

(57) ABSTRACT

A target contains a target material and a supporting element connected thereto, characterized in that the target material is configured as an outer ring. The outer ring is divided in the circumferential direction into two or more segments, which contain a brittle material with a plastic elongation at break at 20° C. of less than or equal to 2%. A supporting element is configured as an inner ring and is formed from copper or a copper alloy. A method teaches the production of the target having the inner and outer rings.

The present invention relates to a segmented ring target. The present invention further relates to a method for producing such a target.

In the prior art, targets for use in physical vapor deposition processes (PVD processes) are known, by means of which layers are deposited from the gas phase, such as arc evaporation or also atomization, hereinafter also referred to as sputtering. The present invention particularly relates to sputter targets, as they are used in a PVD sputtering process for depositing layers onto a substrate material provided for this purpose. Such sputter targets always comprise the target material and, depending on the target material, optionally a support element connected thereto, possibly via a bonding layer, typically designed as a backing plate.

Most sputter targets are so-called planar targets, which can be circular or rectangular in shape. However, these planar targets have the disadvantage that only about 30% to 40% of the material from which they are made is effectively sputtered.

To increase the effectiveness of sputtering, more and more tubular targets are being used. However, their production is technologically more difficult than the production of planar targets. This is particularly the case when the tubular sputter targets consist of brittle materials or contain brittle materials.

Targets are subjected to mechanical and thermomechanical stresses during their use in a coating plant, which can lead to bending and/or tensile stresses. In particular, the industrially required process control with high power densities to accelerate the coating processes through higher deposition rates requires very good cooling to reduce thermal stress and thereby induced mechanical stress and tensions, respectively, which can lead to the fracture of targets made of brittle materials. The use of coolants, typically water at high pressure, forces the equipment of the targets with an internally arranged support element, typically an inner tube as a coolant-carrying support structure, on which the target material is applied. The pressure of the cooling water on the inside of the cooling tube can lead to its expansion, whereby the target material resting on it is mechanically stressed through elastic deformation and can be damaged.

Such a support element can also additionally serve as a heat sink, i.e., by applying a support element with a thermal conductivity increased compared to the coating material, the heat generated in the coating process can be better dissipated. In such a case, the entire arrangement of target material and support element is referred to as a target. Such support elements/heat sinks can be applied to coating materials with low toughness (brittle material behavior) by various methods, such as soft soldering or brazing with known solders. However, it is a particular technical challenge to connect the target material in the case of a tubular target with the support element/tube, since the target material cannot be easily produced as a tube via the powder metallurgical route, as is usual for brittle materials.

In typical industrial designs of tubular targets, these are usually designed monolithically and thus without a support element in the case of ductile metals or metal alloys, or in the case of potential corrosion in contact with the coolant, provided with corrosion protection layers such as electroplated nickel layers. For metallic materials with low plastic elongation at break, these can be applied in a hot isostatic pressing process (HIP) onto the carrier tube with higher strength or elongation at break, respectively, in combination with the densification process from powdered components during the HIP process. In further designs of targets made of metals or metal alloys, these can be inserted into each other by shrink-fitting using the expansion of the target tube by heating and the shrinking of the support element tube by cooling and connected by adjusting to room temperature via the shrink fit without the use of intermediate layers. Another typical design for brittle target materials consists of a tubular target that has a significantly larger inner diameter than the outer diameter of the support element tube and in which the space created between the two components thereby is filled with liquid indium or another low-melting solder and solidified. The disadvantage of this design lies, due to the low melting point of the solder material, in the limited ability to withstand high thermal loads that can arise from high sputtering powers.

WO 2017/088842 A1 proposes a cylindrical cathode for depositing layers in the PVD process, comprising a tubular central support with a target arranged on its circumference, wherein the central support is provided with a flow space at least in the area of the target, which is separated from the target by an elastic tube. In the case that the target is made of brittle, difficult-to-machine materials, such as TiB₂ or B₄C, the target material is produced in the form of rings and these are pushed onto the tube side by side. The thin elastic tube deforms under pressure from the cooling water during operation and thus adapts to the inside of the rings. WO 2017/088842 A1 thereby succeeds in avoiding solder or adhesive layers, which due to their reduced thermal load capacity represent the limiting factor in the use of high power densities.

As already mentioned, a mechanical load is generally exerted on the coating source with cooling tubes, in particular with the elastic tube of the device of WO 2017/088842 A1, which in turn can lead to a deformation of the coating source until it breaks. This effect is further intensified by the fact that the thickness of the coating source, in particular of the coating material, is reduced during the coating process. As a result, failure due to breakage is even more likely to occur. In practice, brittle target materials must therefore be enriched with a binder, such as nickel, to prevent them from cracking when the cooling tube/membrane is subjected to water pressure and before it is actually put into operation. In turn, the binder is deposited in the layers deposited with the target, which is undesirable.

The object of the present invention is to provide a more stable target for use with a tubular, coolant-carrying support element in high power density deposition processes.

This object is solved by a target comprising a target material and a support element connected thereto according to claim 1, characterized in that the target material is designed as an outer ring, the outer ring being divided into two or more segments in the circumferential direction and consisting of a brittle material with a plastic elongation at break at 20° C. of less than or equal to 2%, the support element is designed as an inner ring and consists of copper or a copper alloy, and by a method for manufacturing such a target according to claim 8. Advantageous further embodiments of the invention can be seen from the dependent claims, which can be freely combined with one another.

According to the present invention, a target has target material and a support element connected thereto. The target is ring-shaped, since it is composed of an outer ring of target material and an inner ring connected thereto as a support element.

Geometrically, the target has the shape of a ring, i.e. the shape of a special hollow cylinder with an outer radius R, an inner radius r and a height h, whereby the height h of the hollow cylinder is lower than the outer radius R and the outer radius R and the inner radius r are assigned to concentric circles. Such a special hollow cylinder is also referred to as a perforated disk with a concentric, circular opening. The wall thickness b results from the difference between the outer radius and the inner radius: b=R−r.

R is typically in the range from 40 mm to 300 mm and r in the range from 30 mm to 290 mm, with the proviso that b is in the range from 10 mm to 50 mm. The height h is in the range from 10 mm to 100 mm. The ratio of the target material thickness hₛ to the copper ring thickness is typically in a range of 1:1 to 10:1.

The height of the inner ring can be 0.01 mm to 0.8 mm, preferably 0.2 mm to 0.6 mm greater than the width bₛ of the segments of the outer ring made of the target material. This makes it possible to achieve a defined gap between the ring targets assembled to form an arrangement on a cooling tube.

The target material is designed as an outer ring interrupted in the circumferential direction and consists of a brittle material, whereby the ring is divided into two or more segments and the support element is designed as an inner ring made of back-cast copper or copper alloy.

The segmentation of the ring made of the target material makes it possible to permanently bond the materials of the target material and the support element in a way that withstands the component stresses in use as a sputtering target with high power and thus high, possibly cyclical thermomechanical stresses. Copper and copper alloys, which are used here as support elements, have a high coefficient of thermal expansion (CTE) in the order of 16.5×10⁻⁶ K⁻¹. The coefficients of expansion of the brittle materials considered here, in particular ceramic materials, are in the range of 5×10⁻⁶ K⁻¹ to 8×10⁻⁶ K⁻¹ and therefore lower by a factor of approx. 2. This difference in the CTE values must be taken into account due to the multi-part design of the outer ring made of the target material, as it shrinks far less than the copper or copper alloy during the cooling phase of the inner ring attached via the back-casting of molten copper or copper alloy. For this reason, defined gaps (recesses) must be created between the individual ring segments before the back-casting process, preferably with the aid of filling material made from compressible graphite foils. The width of the gaps to be created is a function of the number of ring segments as well as the difference between the CTE values of the target material and the copper material used.

The use of copper or some copper alloys is advantageous in view of the low yield strength of these materials at high temperatures. This makes it possible for a large proportion of the stresses that arise during cooling in the contact zone between the target material and the support element, resulting from the aforementioned differences in the CTE values, to be relieved by plastic deformation.

Segmentation therefore makes it possible to manufacture a coating source with a coating material made of a brittle material and to operate the coating source stably, i.e. without structural failure, such as cracking or breaking, of the target material, at very high power densities. In particular, it should be mentioned that the direct bonding of the target material to the support element, without the use of low-melting solders, means that the thermal stability of the target is very high and is in principle stable up to the drastic drop in the yield strength of the copper at temperatures just before the melting point of the copper or the copper alloy used.

The target material consists of a brittle material. In the context of this description, brittle materials are those that break close to the elastic limit with little or no plastic deformation. These materials, and thus also the sputtering targets made from them, therefore have only a low plastic deformation capacity.

In the context of the present invention, brittle materials are materials with an elongation at break at room temperature (20° C.) of less than or equal to 2%, preferably less than or equal to 1% and further preferably less than or equal to 0.2%.

Suitable brittle materials for the purposes of the present invention are selected from the group consisting of ceramic materials, metallic materials, semi-metallic materials, intermetallic phases and mixtures of these materials.

Preferred brittle materials are selected from the group consisting of borides optionally doped with carbon, nitrides, carbides, silicides, oxides, chromium, chromium alloys with a chromium content of at least 50 at % chromium, metallic materials, semi-metallic materials, intermetallic TiAl phases, intermetallic AlCr phases and mixtures of these materials.

Particularly preferred brittle materials are selected from the group consisting of TiB₂, VB₂, W₂B₅, CrB₂, TaB₂, WC, WC/C, TiC, SiC, SiC/C, B₄C, B₄C/C, TiN, AlN, TiSi₂, CrSi₂, MoSi₂, Cr, Si, Ge and mixtures of these aforementioned materials.

To ensure stable process control during sputtering, the target material typically has a density higher than 80% of the theoretical density, preferably higher than 90%, more preferably higher than 95%, more preferably 98% to 100%. By definition, the theoretical density applicable to the respective composition of the target material is calculated from the mean value of the theoretical densities of the individual phase components weighted by the mole fractions. The actual density of the target material is determined using Archimedes' principle.

Preferably, the outer ring is divided into 2 to 16, more preferably 4 to 12 and more preferably 6 to 8 segments. When dividing the ring from the target material into the individual segments, an optimum should be sought between the following competing features: minimization of the stresses in the contact zone between the target material and the support ring by using as many segments as possible, simplicity of the design of the arrangement when back-casting with the copper or copper alloy by using as few segments as possible, cost-effectiveness of production through optimum, near-net-shape production of the segments from the target material, which is best achieved when dividing into 6 to 8 segments.

According to a further development of the invention, all segments of a ring have the same dimensions. This has the advantage that segments for manufacturing the ring-shaped target can be provided from different target materials, as in a modular system, and can then be combined with each other as desired. In one embodiment, such a target only has segments made of the same target material. In another embodiment, the target has segments made of different target materials. This has the advantage that different materials can be simultaneously or co-sputtered on a common target and the composition of the materials can be tailored to the requirements of the PVD layer to be deposited.

It is also possible that a target according to the invention has graphite foil between facing surfaces of two segments adjacent in the circumferential direction. This graphite foil originates from the manufacture of the target and can be used to prevent the penetration of back-cast, liquid copper/copper alloy into recesses between segments adjacent in the circumferential direction during the manufacture of the target. Preferably, the graphite foil is a compressible foil with a thickness of 0.2 mm to 1.5 mm. Such compressible graphite foils are sold as standard products by manufacturers of graphite materials. After production, in the cooled and shrunk state of the back-cast copper/alloy, a correspondingly produced target therefore has graphite-filled recesses in a range of 0.01 mm to 0.8 mm. Preferably, the graphite-filled recesses between the segments are in a range of 0.2 to 0.6 mm.

The support element designed as an inner ring consists of essentially pure, back-cast copper or a copper alloy and has an average grain size of >0.5 mm, preferably >1 mm, particularly preferably >2 mm. The skilled person can also recognize (on a cross-section of the support element) a coarse-grained crystal structure, which is typical for copper/alloy solidified from the melt. This shows no characteristics of a formed, textured material.

Copper alloys are understood herein to be alloys with copper, where copper is the main component and the total proportion of alloying elements is <50 wt. %, preferably <10 wt. % and particularly preferably <5 wt. %. The following copper casting materials are exemplary for copper alloys: CuCr, CuCrZr, CuZn, CuSn, CuSnZn, CuAl, CuMnAl, CoNi and CuMg.

Back-casting with copper/copper alloy provides a stable connection of the target material to the support element, proven even at high power densities. Similar to WO 2017/088842 A1, the present invention succeeds in completely dispensing with the use of classic solder or adhesive connections between the cooling element and the target material. In the present invention, the ring segments are directly adjacent to the inner ring or, in the case of segments made of TiB2 or a TiB₂-based ceramic, are advantageously connected to the inner ring via a titanium-containing intermediate layer. A TiB₂-based ceramic is understood in the present case to be a ceramic which contains at least 50 mol % TiB₂, preferably at least 70 mol % TiB₂ and particularly preferably at least 80 mol % TiB₂. At the same time, the present invention succeeds in counteracting the influence of the pressure of the cooling water used by the special ring shape of the target, the segmentation of the target material and the provision of a ring-shaped support element, thus allowing the target to be operated at extremely high power densities and correspondingly high cooling rates without failure phenomena, such as cracking or breaking, without the need to enrich the target material with binders, such as nickel, and thus increase the ductility. By segmenting the target material, it is also possible to achieve a very high resistance of the target to the cyclical thermomechanical stresses that occur in industrial sputtering operation, which can otherwise lead to damage due to material fatigue in continuous use.

Since the outer wall of the cooling device, typically a copper tube or an elastic copper membrane, as in the case of WO 2017/088842 A1, expands due to the pressure of the cooling water, the ring-shaped targets of the present invention form a force-fit connection with the outer wall of the cooling device and do not have to be connected to the outer wall of the cooling device by a material bond. Due to the particularly high strength of the ring-shaped target provided by the present invention, the pressure in the copper tube or the elastic copper membrane can be set very high in order to achieve a higher heat transfer coefficient without the risk of brittle fracture of the target ring.

In addition, the invention offers the advantage that different rings can be arranged in combination on a target-supporting cooling tube of a system or rings with different material segments can be combined.

The present invention also comprises a method for manufacturing a ring-shaped target described herein.

First, ring segments of a brittle material having a plastic elongation at break at room temperature of less than or equal to 2% are provided. See the definition of elongation at break in DIN EN ISO 6892-1:2019. Production from brittle materials is typically carried out using the powder metallurgy route. The target material is compacted with pressure, heat or pressure and heat and compacted to a density higher than 80% of the theoretical density, preferably higher than 90% and further preferably higher than 95% of the theoretical density.

Common methods known in the state of the art for compacting the material are sintering, pressure sintering, hot isostatic pressing, hot pressing, spark plasma sintering and this as well in an inert gas atmosphere, reducing atmosphere, such as in hydrogen, or in a vacuum.

For the purpose of the present invention, the shaping of the segments can be achieved by direct compaction of the target material in a corresponding mold, segments can be produced by separating a ring formed from compacted target material from a corresponding mold, or preferably a sheet of the target material, for example in the form of a rectangular or round plate, can be produced from which the segments are individually cut out. The segments are preferably cut or removed using spark erosion-based processes such as wire erosion or mechanical cutting processes such as abrasive cutting. The former method is only suitable for electrically conductive materials. Another preferred method is to produce the segments from a sheet of the compacted target material by wire erosion. Advantageously, the thickness of such a plate corresponds to the width bₛ of the segments. If necessary, the exact thickness of the plate can be adjusted by mechanical processing of the plate, advantageously by grinding the plate, after compaction. In this way, precisely shaped segments with very good density homogeneity and high density can be produced in large quantities and with near-net-shape optimum use of material.

This is followed by a step of arranging the ring segments to form an outer ring interrupted by recesses in the circumferential direction in a shape corresponding to the target, preferably made of graphite with an inner punch, whereby the recesses between the ring segments are dimensioned in such a way that they have distances between 0.01 to 0.8 mm, preferably 0.2 to 0.6 mm, between the segments after contraction by cooling of an inner ring produced by back-casting with liquid copper or liquid copper alloy.

The dimensions of the recesses (gaps) can be calculated by the skilled person. The width of the gap to be made is a function of the number of ring segments as well as the difference between the CTE values of the target material and the copper material used.

This relationship can be represented by the following formula:

S_{B}=(2×3.14×R_{KZ}×(CTE_{Cu}−CTE_{TM})×1000K)/N,

where S_{B} is the gap width, R_{KZ} is the radius of the circular contact zone between the target material and the support element, CTE_{Cu} and CTE_{TM} are the expansion coefficients of the copper/alloy and the target material, respectively, and N is the number of ring segments of which the target material consists. The 1000 K roughly corresponds to the solidification interval of the copper or copper alloy. The formula calculates the difference resulting from the CTE differences in the amount of shrinkage along the circumference where the two materials are joined together in the cooling phase of the solidifying copper melt and divides this by the number of gaps to be taken into account.

The method advantageously comprises a step of positioning a compressible graphite foil with a thickness of 0.2 to 1.5 mm in the recesses between the segments in the circumferential direction. This can suppress or prevent the penetration of liquid copper or liquid copper alloy into the recesses between the segments in the circumferential direction.

This is followed by a step of back-casting the outer ring with liquid copper or a liquid copper alloy. Back-casting is the metallurgical application of a material to a base material, in this case the target material, which is always in a solid aggregate state with the process parameters used.

During back-casting, solid copper or copper alloy is applied to the arranged segments of the target material, and optionally graphite foil. Preferably, the copper or copper alloy is present in lumps, more preferably in the form of ingots. The required quantity can be calculated from the density of the copper (8.96 g/cm³) or the copper alloy and the volume between the inner walls of the target segments assembled into a ring and the outer diameter of the graphite cylinder (punch), which is installed in the back-casting mold, and the height of the target rings with a surcharge of preferably at least 2 mm in order to have an oversize for the subsequent mechanical processing of the back-cast blank into the finished target.

This is followed by a step in which the mold, equipped with the segments, copper or copper alloy and possibly graphite foil, is placed in a furnace. The target, which is initially not yet compact and bonded, is heated under a suitable process atmosphere, such as vacuum, H₂, N₂ or inert gas such as Ar, possibly with a ramp function, until the overlying material consisting of copper or a copper alloy melts, filling the space between the non-melting target material and the graphite cylinder in the center of the mold and wetting the inside of the segments of the target material. For example, the melting point for pure copper is 1085° C. The temperature of the furnace should be selected so that the temperature is above the melting point of the copper or above the liquidus line of the copper alloy in the phase diagram, preferably between 50° C. and 100° C. above it. When back-pouring, the furnace must be kept at a temperature above the melting point or the liquidus line for a sufficient period of time so that a complete melt of the copper or copper alloy placed on top can form.

After a desired holding time above the melting point, the furnace is cooled down again to below the melting point of the copper or copper alloy. Cooling is preferably carried out by lowering the component from the hottest zone of the furnace into the colder zone in order to ensure directional solidification without the formation of pores or shrinkage cavities. A stable bond is formed between the segments and the copper/alloy. After solidification of the copper or copper alloy, the cooled target shows a first part consisting of target material which is designed as an outer ring, whereby the outer ring is divided into two or more segments in the circumferential direction and consists of a brittle material with a plastic elongation at break at 20° C. of less than or equal to 2%, and a second part which is designed as a supporting element as an inner ring and consists of copper or a copper alloy.

Typically, this is followed by a step of mechanical processing or reworking of the solidified target, in particular to the final dimensions, by turning, milling, cutting, grinding, lapping, in particular by turning or milling.

Subsequently, welding, soldering, joining, shrinking or gluing processes can also be carried out on the target, in particular for fitting a cooling tube. The target can also be engraved afterwards. In addition to the mechanical processing of the target, thermal post-treatment of the target can also be carried out, such as annealing or annealing and tempering, in order to achieve the desired structural properties, in particular of the support element made of copper and in particular of copper alloy, which can be optimized in this way with regard to the high hardness.

In the event that the segments are TiB₂ or a TiB₂-based ceramic, the inner side of the outer ring is advantageously coated with a layer of titanium before the back-casting step. Preferably, the titanium layer is applied in a thickness of 10 to 100 μm, typically by thermal spraying or cold gas spraying, preferably by cold gas spraying.

Further advantages and usefulness of the invention will become apparent from the following description of embodiments with reference to the accompanying figures.

The figures show:

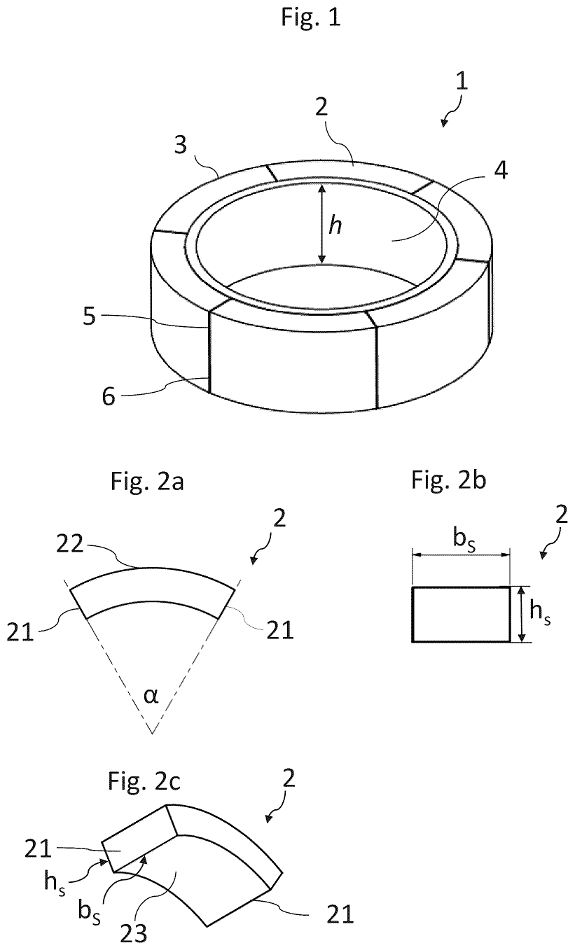

FIG. 1: a perspective view of a ring target according to the invention;

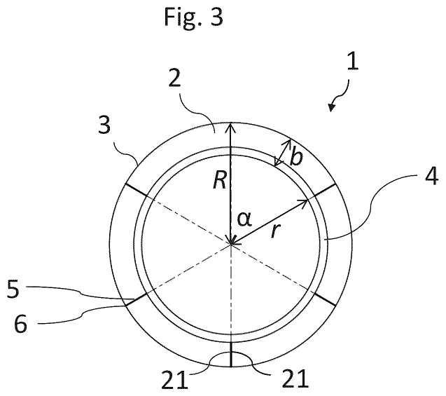

FIG. 2a: a side view of a segment for manufacturing a ring target according to the invention;

FIG. 2b: a cross-sectional view of a segment for manufacturing a ring target according to the invention;

FIG. 2c: a perspective view of a segment for manufacturing a ring target according to the invention;

FIG. 3: a top view of a ring target according to the invention.

FIG. 1 shows a target 1 according to the invention with an outer ring 3 formed of segments 2 and an inner ring 4. Segments 2 are separated from each other in the circumferential direction of the outer ring 3 by a gap 5. The gap 5 can be filled with a graphite foil 6. In addition, the total height of the target according to the invention is indicated by h.

FIG. 2a shows a lateral view of a segment 2 for manufacturing a target 1 according to the invention shown in FIG. 1. The segment 2 extends with its outer side 22 along a section of the outer circumference of the outer ring 3 and, as part of an outer ring 3, has a circular arc shape. The segment 2 has lateral connection surfaces 21 for connection to an adjacent segment 2. The connection surfaces 21 are shown as an example following the radius and oriented orthogonally to the circumferential direction. However, it is also conceivable that the connecting surfaces 21 are oriented differently, with the proviso that neighboring connecting surfaces 21 of neighboring segments 2 are oriented parallel to each other. By attaching the connecting surfaces at an angle that is not parallel to the radius of the ring target, it would also be possible to ensure that the gaps are not aligned frontally to the plasma in the coating chamber if they are not filled with graphite foils. The angle α shown here corresponds to approximately 60° in the case of the segmentation into 6 segments shown here as an example and originates from the center of the concentric circles that delimit the target 1, so that the segment 2 shown as an example extends approximately over a section of one-sixth of the outer ring 3. The segment 2 describes a part of an outer ring 3 of a target 1 according to the invention, which comprises several segments 2 and is interrupted in a circumferential direction. According to the invention, segments 2 can also extend over a larger or smaller section of the outer ring 3.

As shown in FIG. 2b, the segment 2 has a rectangular cross-sectional area with a height hₛ and a width bₛ perpendicular to the circumferential direction.

FIG. 2c shows a perspective view of the segment 2 with an inner surface 23 extending along a section of the inner circumference of the outer ring 3. The inner surface 23 has a layer of elemental titanium in the event that the segment is a segment made of TiB₂ or a TiB₂-based ceramic.

FIG. 3 shows a top view of the target 1 according to the invention. The outer radius R and the inner radius r of the concentric circles that delimit the target 1 are shown. The wall thickness b of the target results from the difference R−r. The segments 2 shown here comprise approximately ⅙ of the outer ring 3 in the circumferential direction to produce a target 1 with an outer ring 3 with six identical segments 2, optionally together with any graphite-filled gaps 5, 6 due to the manufacturing process. According to the invention, an outer ring 3 can also comprise fewer, preferably two, three, four or five or more, preferably seven, eight, nine, ten, eleven or twelve segments 2. The segments 2 of a ring 3 can also have different dimensions in the circumferential direction. The adjacent surfaces 21 of two adjacent segments 2 are typically aligned parallel to each other, preferably following the radius, orthogonal to the circumferential direction of the outer ring 3, so that the gaps 5 can be kept as narrow as possible.

Segments 2 consist of a brittle material as defined herein as target material. An outer ring 3 can consist of segments 2 made of identical target material or of segments 2 made of different target materials. The target 1 of FIG. 3 also shows the inner ring 4 consisting of back-cast copper/alloy in direct contact with the inner surface 23 of the segments 2 of the outer ring 3. In the case of TiB₂ or a TiB₂-based ceramic, the target has a titanium-containing layer between the inner surface 23 of the segments 2 and the inner ring 4 consisting of copper/alloy (not shown). During the back-casting process, the titanium largely goes into solution with the copper/alloy and a titanium-containing intermediate layer is then formed, which consists of titanium and copper or titanium and copper alloy.

The height of the inner ring 4 can correspond to the width bₛ of the segments 2. However, it is also possible for the height of the inner ring 4 to be 0.01 to 0.8 mm, preferably 0.2 to 0.6 mm, greater than the width bₛ of the segments 2 of the outer ring 3 made of the target material. This makes it possible to achieve a defined gap between the target rings built up to form an arrangement on the cooling tube.

### Examples of Manufacture:

For the examples according to the invention, segments, with bₛ=30 mm and hₛ=22 mm, were made from target materials for an outer ring, as follows:
TiB₂, six identical segments, with an inner surface of the segments coated via CGS titanium before back-casting
TiB₂, three identical segments, with the inner surface of the segments coated with titanium over CGS before back-casting
VB₂, six identical segments
W₂B₅, six identical segments
TaB₂, six identical segments
WC, two identical segments
   was compacted into a plate by hot pressing powders of the respective target material, which was then ground to a thickness of 30 mm and served as a pre-material for cutting out segments by wire EDM.

In the case of TiB₂, the inner surface of the TiB₂ segments was coated with a 50 μm layer of pure titanium using CGS before back-casting. The following CGS process parameters were used for the titanium layer (see Table 1):

TABLE 1

| | | | | Temper- | Layer |
|---|---|---|---|---|---|
| | | Process | Pres- | ature of | thick- |
| Sample | Powder | gas | sure | gas | ness |
| TiB₂ | Ti-Powder (grade 1, | N₂ | 50 bar | 1000° C. | 50 μm |
| segment | 15-45 μm; d50 28, 5 | | | | |
| | μm) | | | | |

The segments were then back-cast with copper. The segments are arranged in a graphite mold corresponding to the target to form an outer ring and adjacent segment surfaces are separated from each other by graphite foil. Copper part(s) (cylinders cut from copper rods) made of essentially pure copper were placed on the mold.

The graphite mold was then placed in a furnace and heated to 1150° C. in an H₂ atmosphere. After reaching 1150° C., the graphite molds were kept in an N₂ atmosphere at the temperature of 1150° C. for 1 hour (note: above the melting temperature of copper, which is 1085° C.). The graphite mold was then lowered out of the hot zone of the furnace at a speed of 33 cm/h. The cooling of the segment-copper composite thus took place via a directed solidification of the melt, which led to a largely stress-free, but coarsely crystalline microstructure of the back-cast copper. After final cooling to room temperature, targets back-cast with copper in this way show a very good bond between the two materials (target material and copper). Targets produced in this way show no cracks or delamination at the interface between the two materials. The slow cooling process also minimizes the thermal stresses between the segments made of brittle materials and the solidified copper inner ring.

The targets were then machined to their final dimensions by turning. The inside of the copper inner ring was machined to the inner diameter of 80.8 mm specified in the drawing and the height of the copper ring to 30.2 mm in order to achieve an oversize of 0.1 mm on both sides compared to the 30 mm high outer ring of the target material. Targets with the following dimensions are obtained: Ø110/80.8×30.2 mm. Finally, the ceramic sides of the targets were cleaned by blasting with glass beads and checked for compliance with the dimensions specified in the drawings.

The targets were successfully tested in sputtering mode in a coating system in continuous operation without any failures.

1-13. (canceled)

14. A target, comprising:
a support element configured as an inner ring and made of copper or a copper alloy; and
a target material configured as an outer ring and connected to said support element, said outer ring being divided in a circumferential direction into at least two segments containing a brittle material with a plastic elongation at break at 20° C. of less than or equal to 2%.

15. The target according to claim 14, wherein said target material has a density higher than 80% of a theoretical density.

16. The target according to claim 14, wherein said brittle material is selected from the group consisting of ceramic materials, metallic materials, semi-metallic materials, intermetallic phases and mixtures of at least two of said ceramic materials, said metallic materials, said semi-metallic materials, and said intermetallic phases.

17. The target according to claim 14, wherein said brittle material is selected from the group consisting of borides, nitrides, carbides, silicides, and oxides.

18. The target according to claim 14, wherein said outer ring has 2 to 16 of said segments.

19. The target according to claim 14,
further comprising graphite foil; and
wherein said segments having facing surfaces, said graphite foil is disposed between said facing surfaces of two adjacent said segments.

20. The target according to claim 14, wherein said segments are directly connected to said support element or said segments consist of TiB₂ or a TiB₂-based ceramic and are connected to said support element via a titanium-containing intermediate layer.

21. The target according to claim 14, wherein said target material has a density higher than 90% of a theoretical density.

22. The target according to claim 14, wherein said target material has a density higher than 95% of a theoretical density.

23. The target according to claim 17, wherein said borides, said nitrides, said carbides, said silicides and said oxides are doped with at least one of carbon, chromium, chromium alloys with a chromium content of at least 50 at % chromium, metallic materials, semi-metallic materials, intermetallic TiAl phases, intermetallic AlCr phases and mixtures of said materials.

24. A method for producing a ring-shaped target, which comprises the following steps of:
providing ring segments made of a brittle material with a plastic elongation at break at room temperature of less than or equal to 2%;
disposing the ring segments in a mold to form an outer ring interrupted by recesses in a circumferential direction, the recesses being dimensioned such that, after contraction by cooling of an inner ring produced by back-casting with liquid copper or liquid copper alloy, the recesses are spacings of between 0.01 mm and 0.8 mm between the segments;
back-casting the outer ring with liquid copper or a liquid copper alloy in a vacuum or in a protective gas atmosphere to produce the inner ring connected to the outer ring as components of the ring-shaped target; and
cooling the ring-shaped target.

25. The method according to claim 24, wherein the step of providing the ring segments is preceded by a production of the ring segments, which comprises the following steps of:
providing the brittle material in powder form;
compacting the brittle material to a density higher than 80% of a theoretical density to form a flat structure; and
cutting out the ring segments by means of wire erosion.

26. The method according to claim 24, wherein the step of disposing the segments includes a positioning of a compressible graphite foil with a thickness of 0.2 to 1.5 mm in the recesses.

27. The method according to claim 24, which further comprises using a mold made of graphite as the mold.

28. The method according to claim 24, wherein the step of disposing and the step of back-casting immediately follow each other or the segments are made of TiB₂ or a TiB₂-based ceramic and before the step of disposing and the step of back-casting an intermediate titanium layer is applied to an inner side of the segments made of said TiB₂ or said TiB₂-based ceramic.

29. The method according to claim 24, wherein the ring-shaped target is mechanically finished to final dimensions.

30. The method according to claim 24, which further comprises mechanical reworking of the ring-shaped target.

31. The method according to claim 25, which further comprises compacting the brittle material to a density higher than 90% of the theoretical density.

32. The method according to claim 25, which further comprises compacting the brittle material to a density higher than 95% of the theoretical density.
